(19) United States
(12) Patent Application Publication
(10) Pub. No.: US 2009/0289342 A1
(43) Pub. Date: Nov. 26, 2009

(54) Semiconductor Device and Semiconductor Device Manufacturing Method

(75) Inventors: Yasumasa Kasuya, Kyoyo (JP); Sadamasa Fujii, Kyoto (JP)

Correspondence Address: RABIN & Berdo, PC, 1101 14TH STREET, NW, SUITE 500, WASHINGTON, DC, 20005, US

(73) Assignee: ROHM CO., LTD, Kyoyo (JP)

(21) Appl. No.: 11/918,211

(22) PCT Filed: Apr. 12, 2006
(86) PCT No.: PCT/JP2006/307777

§ 371 Date: Oct. 11, 2007

(30) Foreign Application Priority Data
Apr. 15, 2005 (JP) 2005-1185665
Apr. 15, 2005 (KP) 2005-118564

(51) Int. Cl. H01L 23/12; H01L 21/441

(52) U.S. Cl. 257/690; 438/637; 257/E23.003; 257/E21.477

(57) ABSTRACT

In an inventive semiconductor device production method, a one-side metal layer is first formed in a region located across a predetermined section line on one surface of a substrate. Further, an other-side metal layer is formed on the other surface of the substrate in a position opposed to the one-side metal layer. In turn, a continuous through-hole extending continuously through the other-side metal layer and the substrate is formed in a position located across the section line. Thereafter, a metal plating layer is formed on a surface of the other-side metal layer, an inner surface of the continuous through-hole and a portion of the one-side metal layer exposed to the continuous through-hole. Before the resulting substrate is cut into separate support boards, a portion of the other-side metal layer present on the section line and a portion of the metal plating layer present on this other-side metal layer portion are removed.

### TECHNICAL FIELD

The present invention relates to a semiconductor device including a semiconductor chip and a support board which supports the semiconductor chip, and a production method for such a semiconductor device.

### BACKGROUND ART

There is conventionally known a semiconductor device which includes a semiconductor chip and a support board supporting the semiconductor chip on one surface thereof and is adapted to be mounted on a mount board (wiring board) with the other surface thereof being opposed to a surface of the mount board.

Internal terminals for electrical connection to the semiconductor chip are provided on the one surface of the support board to which the semiconductor chip is bonded. External terminals for electrical connection to lands (electrodes) of the mount board are provided on the other surface of the support board opposite from the one surface. The support board has grooves formed in a side face thereof. Interconnections are provided on inner surfaces of the grooves. The internal terminals are respectively electrically connected to the external terminals via the interconnections.

The support board is obtained by cutting an insulative substrate formed with patterns of internal terminals, external terminals, interconnections and the like along section lines (dicing lines) defined in a lattice form by a cutting tool such as a dicing blade. More specifically, the internal terminals are each formed across the section line on one surface of the substrate. The external terminals are each formed on the other surface of the substrate in a position opposed to the internal terminal. Then, through-holes are each formed across the section line as extending through the internal terminal, the substrate and the external terminal. Metal plating layers are each formed on an inner surface of the through-hole. Therefore, when the substrate is cut along the section lines, the internal terminals and the external terminals are each divided into portions disposed on separate support boards on opposite sides of the section line, and the through-holes are each divided into grooves disposed in side faces of the support boards on the opposite sides of the section line. Thus, the support board is provided, which has a construction such that the internal terminals are respectively connected to the external terminals via the interconnections formed on the inner surfaces of the grooves. Semiconductor chips may be respectively bonded onto bonding areas of the substrate surrounded by the section lines, for example, before the substrate is cut into the separate support boards.

### Patent Document 1: Japanese Patent No. 3214619

### DISCLOSURE OF THE INVENTION

### Problems to be Solved by the Invention

However, the external terminals, which are composed of a metal and hence ductile, are liable to have so-called metal burrs when the substrate is cut by the cutting tool, because the cutting tool cuts into the substrate from the one surface to the other surface of the substrate to drag and draw the external terminals. The metal burrs of the external terminals are liable to cause electrical short-circuit between the external terminals. Further, the metal burrs are brought into abutment with the surface of the mount board to raise the semiconductor device from the mount board, resulting in insufficient connection between the external terminals and the lands on the surface of the mount board.

It is therefore an object of the present invention to provide a semiconductor device having a burr-free external terminal, and a production method for the semiconductor device.

### Means for Solving the Problems

A semiconductor device according to one aspect of the present invention comprises a semiconductor chip, a support board which supports the semiconductor chip on one surface thereof, an internal terminal provided on the one surface of the support board and electrically connected to the semiconductor chip, an external terminal provided on the other surface of the support board opposite from the one surface and extending inward from a position spaced a predetermined distance from an edge of the support board, and an interconnection extending through the support board from the one surface to the other surface of the support board and connecting the internal terminal and the external terminal.

The external terminal extends inward from the position spaced the predetermined distance from the edge of the support board on the other surface of the support board. That is, the external terminal is not present in a region of the other surface of the support board having a predetermined width along the edge of the support board. Therefore, even if the cutting tool is moved to cut into a substrate from one surface (equivalent to the one surface of the support board) to the other surface of the substrate for cutting the substrate along a section line into separate support boards, a metal of the external terminal is unlikely to be dragged and drawn by the cutting tool. This eliminates the possibility that a metal burr occurs on the external terminal. Therefore, the semiconductor device has no metal burr on the external terminal and, therefore, is free from electrical short-circuit between external terminals and insufficient connection (mounting failure) between the external terminal and a land on a mount board, which may otherwise occur when the semiconductor device is mounted on the mount board.

The support board may have a groove formed in a side face thereof as extending from the one surface to the other surface thereof and opening in the side face, and the interconnection may be provided on an inner surface of the groove.

The semiconductor device having such a construction can be produced, for example, by a method comprising the steps of: forming a one-side metal layer in a region located across a predetermined section line on one surface of an insulative substrate; forming an other-side metal layer on the other surface of the substrate opposite from the one surface in a position opposed to the one-side metal layer perpendicularly to the one surface; forming a continuous through-hole extending continuously through the other-side metal layer and the substrate in a position located across the section line; forming a metal plating layer on a surface of the other-side metal layer, an inner surface of the continuous through-hole and a portion of the one-side metal layer exposed to the continuous through-hole by plating; after the plating step, removing a portion of the other-side metal layer and a portion of the metal plating layer which are present on the section line on the other surface of the substrate; and, after the metal removing step, cutting the resulting substrate along the section line into separate support boards by moving the substrate and a cutting tool relative to each other to cause the cutting tool to cut into the substrate from the one surface to the other surface of the substrate.

In this method, the portion of the other-side metal layer on the section line and the portion of the metal plating layer present on the other-side metal layer portion are removed before the substrate is cut into the separate support boards.

By cutting the substrate along the section line, the one-side metal layer disposed across the section line is divided into two parts. After the division, the resulting one-side metal layers serve as internal terminals of support boards on opposite sides of the section line. Further, a portion of the metal plating layer present on the inner surface of the continuous through-hole and on the portion of the one-side metal layer exposed to the continuous through-hole is divided into two parts. After the division, the resulting metal plating layers serve as interconnections respectively connected to the internal terminals of the support boards on the opposite sides of the section line. Further, the resulting other-side metal layers and portions of the metal plating layer present on the surfaces of these other-side metal layers serve as external terminals of the support boards.

When the substrate is cut by the cutting tool, metals of the external terminals are not present on the section line. Therefore, the metals of the external terminals are unlikely to be dragged and drawn by the cutting tool. This eliminates the possibility that metal burrs occur on the external terminals. Accordingly, the semiconductor device produced by the above-mentioned production method has no metal burrs on the external terminals and, therefore, is free from electrical short-circuit between external terminals and insufficient connection (mounting failure) between the external terminal and a land on a mount board, which may otherwise occur when the semiconductor device is mounted on the mount board.

The support board may have a recess dented from the other surface toward the one surface thereof and opening in the side face thereof and a through-hole extending therethrough from the one surface to the other surface thereof and communicating with the recess, and the interconnection may be provided on an inner surface of the through-hole.

The semiconductor device having such a construction can be produced, for example, by a method comprising the steps of: forming a one-side metal layer in a region located across a predetermined section line on one surface of an insulative substrate; forming an other-side metal layer on the other surface of the substrate opposite from the one surface in a position opposed to the one-side metal layer perpendicularly to the one surface; forming continuous through-holes each extending continuously through the other-side metal layer and the substrate in two positions located symmetrically with respect to the section line; forming a metal plating layer on a surface of the other-side metal layer, inner surfaces of the continuous through-holes and portions of the one-side metal layer exposed to the continuous through-holes by plating; after the plating step, forming a recess in a region located between the two continuous through-holes and having a width not smaller than a width of the other-side metal layer as measured along the section line, the recess being dented from the other surface toward the one surface of the substrate and communicating with the two continuous through-holes; and, after the recess forming step, cutting the resulting substrate along the section line into separate support boards by moving the substrate and a cutting tool relative to each other to cause the cutting tool to cut into the substrate from the one surface to the other surface of the substrate.

In this method, the continuous through-holes are formed in the two positions located symmetrically with respect to the section line as each extending continuously through the other-side metal layer and the substrate. After the plating step, the recess is formed in the region located on the section line between the two continuous through-holes.

By cutting the substrate along the section line, the one-side metal layer disposed across the section line is divided into two parts. After the division, the resulting one-side metal layers serve as internal terminals of support boards on opposite sides of the section line. Further, the recess communicating with the two continuous through-holes is divided into two parts by the cutting along the section line. After the division, the resulting recesses serve as recesses of the support boards on the opposite sides of the section line. The two continuous through-holes serve as through-holes communicating the recesses of the support boards. Portions of the metal plating layer present on the inner surfaces of the through-holes (continuous through-holes) and on portions of the one-side metal layer exposed to the through-holes serve as interconnections respectively connected to the internal terminals. Further, the resulting other-side metal layers and portions of the metal plating layer present on these other-side metal layers serve as external terminals of the support boards.

When the substrate is cut by the cutting tool, metals of the external terminals and the interconnections are not present on the section line. Therefore, the metals of the external terminals and the interconnections are unlikely to be dragged and drawn by the cutting tool. This eliminates the possibility that metal burrs occur on the external terminals and the interconnections. Accordingly, the semiconductor device produced by the above-mentioned production method has metal burrs neither on the external terminals nor on the interconnections. Therefore, it is possible to more assuredly prevent electrical short-circuit between external terminals and insufficient connection (mounting failure) between the external terminal and a land on a mount board.

A semiconductor device according to another aspect of the present invention comprises a semiconductor chip, a support board which supports the semiconductor chip on one surface thereof, an internal terminal provided on the one surface of the support board and electrically connected to the semiconductor chip, an external terminal provided on the other surface of the support board opposite from the one surface and extending inward from an edge of the support board, and an interconnection extending through the support board from the one surface to the other surface of the support board and connecting the internal terminal and the external terminal. The external terminal unitarily includes a thinner portion disposed along the edge of the support board and having a relatively small thickness, and a thicker portion disposed inward of the thinner portion and having a relatively great thickness.

The external terminal unitarily includes the thinner portion disposed along the edge of the support board and having a relatively small thickness, and the thicker portion disposed inward of the thinner portion and having a relatively great thickness. That is, a portion of the external terminal adjacent to the edge of the support board (thinner portion) has a relatively small thickness, and a portion of the external terminal present in an inward region of the support board (thicker portion) has a relatively great thickness. Therefore, even if metal burrs having a length not greater than the height of a step between the thinner portion and the thicker portion occur on the thinner portion of the external terminal during production of the semiconductor device, the burrs are not brought into abutment with a surface of a mount board when the semiconductor device is mounted on the mount board. Therefore, a mounting failure such as insufficient connection between the external terminal and a land on the mount board is unlikely to occur.

The semiconductor device having such a construction can be produced, for example, by a method comprising the steps of: forming a one-side metal layer in a region located across a predetermined section line on one surface of an insulative substrate; forming an other-side metal layer on the other surface of the substrate opposite from the one surface in a position opposed to the one-side metal layer perpendicularly to the one surface; forming a continuous through-hole extending continuously through the other-side metal layer and the substrate in a position located across the section line; forming a first metal plating layer on a surface of the other-side metal layer, an inner surface of the continuous through-hole and a portion of the one-side metal layer exposed to the continuous through-hole by a first plating process; forming a second metal plating layer on a surface of the first metal plating layer except for a region extending along the section line and having a predetermined width (which is smaller than the width of the other-side metal layer) across the section line by a second plating process; and, after the second plating step, cutting the resulting substrate along the section line into separate support boards by moving the substrate and a cutting tool relative to each other to cause the cutting tool to cut into the substrate from the one surface to the other surface of the substrate.

In this method, after the first metal plating layer is formed on the surface of the other-side metal layer on the other surface of the substrate, the second metal plating layer is formed on the surface of the first metal plating layer except for the predetermined-width region on the section line. Thereafter, the substrate is cut along the section line by the cutting tool.

When the substrate is cut, only the other-side metal layer and the first metal plating layer are present in the region along the section line on the other surface of the substrate. Further, the other-side metal layer, the first metal plating layer and the second metal plating layer are present in the other region. That is, the total thickness of the metal layers present in the region along the section line is smaller than the total thickness of the metal layers present in the other region. Therefore, even if metal burrs each having a length smaller than the thickness of the second metal plating layer occur in the region along the section line when the cutting tool is moved to cut into the substrate from the one surface to the other surface of the substrate, the burrs are not brought into abutment with a surface of a mount board when the semiconductor device produced by this production method is mounted on the mount board. Therefore, the semiconductor device is free from a mounting failure such as insufficient connection between the external terminal and a land on the mount board.

By cutting the substrate along the section line, the one-side metal layer disposed across the section line is divided in two parts. After the division, the resulting one-side metal layers serve as internal terminals of support boards on opposite sides of the section line. Further, a portion of the first metal plating layer present on the inner surface of the continuous through-hole and on the portion of the one-side metal layer exposed to the continuous through-hole is divided into two parts by the cutting along the section line. After the division, the resulting first metal plating layers serve as interconnections respectively connected to the internal terminals of the support boards on the opposite sides of the section line. Further, the other-side metal layer and a portion of the first metal plating layer present on the other-side metal layer are each divided into two parts. After the division, the resulting other-side metal layers, the resulting first metal plating layers and portions of the second metal plating layer present on these first metal plating layers serve as external terminals of the support boards.

The semiconductor device preferably further comprises a burr preventing layer provided on a side of the thinner portion opposite from the support board and having a thickness not greater than a thickness difference between the thinner portion and the thicker portion.

The semiconductor device having such a construction can be produced, for example, by a method comprising the steps of: forming a one-side metal layer in a region located across a predetermined section line on one surface of an insulative substrate; forming an other-side metal layer on the other surface of the substrate opposite from the one surface in a position opposed to the one-side metal layer perpendicularly to the one surface; forming a continuous through-hole extending continuously through the other-side metal layer and the substrate in a position located across the section line; forming a first metal plating layer on a surface of the other-side metal layer, an inner surface of the continuous through-hole and a portion of the one-side metal layer exposed to the continuous through-hole by a first plating process; after the first plating step, forming an insulative resin layer of an insulative resin across the section line on the other surface of the resulting substrate so as to cover a portion of the first metal plating layer on the other-side metal layer across an entire width of the first metal plating layer defined along the section line; forming a second metal plating layer on a surface of the first metal plating layer by a second plating process; and, after the second plating step, cutting the resulting substrate along the section line into separate support boards by moving the substrate and a cutting tool relative to each other to cause the cutting tool to cut into the substrate from the one surface to the other surface of the substrate.

In this method, the insulative resin layer is formed on the section line as covering the entire width of the first metal plating layer defined along the section line after the first metal plating layer is formed on the surface of the other-side metal layer on the other surface of the substrate. After the second metal plating layer is formed on the surface of the first metal plating layer, the substrate is cut along the section line into the separate support boards.

By cutting the substrate along the section line, the one-side metal layer disposed across the section line is divided in two parts. After the division, the resulting one-side metal layers serve as internal terminals of support boards on opposite sides of the section line. Further, portions of the first metal plating layer and the second metal plating layer present on the inner surface of the continuous through-hole and on the portion of the one-side metal layer exposed to the continuous through-hole are each divided into two parts by the cutting along the section line. After the division, the resulting first metal plating layers and the resulting second metal plating layers serve as interconnections respectively connected to the internal terminals of the support boards on the opposite sides of the section line. Further, the other-side metal layer and a portion of the first metal plating layer present on the other-side metal layer are each divided into two parts. After the division, the resulting other-side metal layers, the resulting first metal plating layers and portions of the second metal plating layer present on these first metal plating layers serve as external terminals of the support boards. When the other-side metal layer and the first metal plating layer are divided, the insulative resin layer on the first metal plating layer is also divided into two parts. After the division, the resulting insulative resin layers serve as burr preventing layers.

When the substrate is cut, the cutting tool is moved to cut into the substrate from the one surface to the other surface of the substrate. The insulative resin layer is present downstream of the first metal plating layer with respect to the direction of the movement of the cutting tool relative to the substrate. Therefore, the insulative resin layer prevents the metal of the first metal plating layer from being dragged and drawn by the cutting tool, thereby preventing occurrence of metal burrs on the external terminal. Thus, the semiconductor device produced by this method has no metal burr on the external terminal and, therefore, is free from a mounting failure such as insufficient connection between the external terminal and a land on a mount board which may otherwise occur when the semiconductor device is mounted on the mount board. Further, the semiconductor device is free from, for example, electrical short-circuit between external terminals due to the metal burrs.

The foregoing and other objects, features and effects of the present invention will become more apparent from the following description of the embodiments with reference to the attached drawings.

### BRIEF DESCRIPTION OF THE DRAWINGS

FIG. 1 is a perspective view schematically illustrating the construction of a semiconductor device according to one embodiment of the present invention.

FIG. 2 is a perspective view of a vicinity of an interconnection of the semiconductor device shown in FIG. 1.

FIG. 3A is a diagram schematically illustrating a lower surface of a substrate for explaining a production method for the semiconductor device shown in FIG. 1 (the step of forming continuous through-holes).

FIG. 3B is a sectional view of the semiconductor device of FIG. 1 taken along a section line A-A shown in FIG. 3A for explaining the semiconductor device production method (the step of forming the continuous through-holes).

FIG. 3C is a sectional view of the semiconductor device of FIG. 1 taken along the section line A-A shown in FIG. 3A for explaining the semiconductor device production method (the step of forming copper plating layers (plating step)).

FIG. 3D is a sectional view of the semiconductor device of FIG. 1 taken along the section line A-A shown in FIG. 3A for explaining the semiconductor device production method (the step of forming nickel/copper plating layers (plating step)).

FIG. 3E is a diagram schematically illustrating the lower surface of the substrate for explaining the production method for the semiconductor device of FIG. 1 (the step of removing portions of lower metal layers, and portions of the copper plating layers and the nickel/gold plating layers present on the lower metal layer portions (metal removing step)).

FIG. 3F is a sectional view of the semiconductor device of FIG. 1 taken along a section line B-B shown in FIG. 3E for explaining the semiconductor device production method (the step of cutting the substrate into separate support boards (cutting step)).

FIG. 4 is a sectional view of an edge portion of the semiconductor device shown in FIG. 1.

FIG. 5 is a sectional view of an edge portion of a semiconductor device according to another embodiment of the present invention;

FIG. 6A is a diagram schematically illustrating a lower surface of a substrate for explaining a production method for the semiconductor device shown in FIG. 5 (the step of forming continuous through-holes).

FIG. 6B is a sectional view of the semiconductor device of FIG. 5 taken along a section line C-C shown in FIG. 6A for explaining the semiconductor device production method (the step of forming the continuous through-holes).

FIG. 6C is a sectional view of the semiconductor device of FIG. 5 taken along the section line C-C shown in FIG. 6A for explaining the semiconductor device production method (the step of forming copper plating layers (plating step)).

FIG. 6D is a diagram schematically illustrating the lower surface of the substrate for explaining the production method for the semiconductor device of FIG. 5 (the step of forming recesses (recess forming step)).

FIG. 6E is a sectional view of the semiconductor device of FIG. 5 taken along a section line D-D shown in FIG. 6D for explaining the semiconductor device production method (the step of forming recesses (recess forming step)).

FIG. 6F is a sectional view of the semiconductor device of FIG. 5 taken along the section line D-D shown in FIG. 6D for explaining the semiconductor device production method (the step of forming nickel/gold plating layers (plating step)).

FIG. 6G is a sectional view of the semiconductor device of FIG. 5 taken along the section line D-D shown in FIG. 6D for explaining the semiconductor device production method (the step of cutting the substrate into separate support boards (cutting step)).

FIG. 7A is a sectional view for explaining a second production method for the semiconductor device shown in FIG. 1 (the step of removing portions of lower metal layers and portions of copper plating layers present on the lower metal layer portions (metal removing step)).

FIG. 7B is a sectional view for explaining the second production method for the semiconductor device shown in FIG. 1 (the step of forming nickel/gold plating layers).

FIG. 8 is a perspective view schematically illustrating the construction of a semiconductor device according to further another embodiment of the present invention.

FIG. 9 is a perspective view of a vicinity of an interconnection of the semiconductor device shown in FIG. 8.

FIG. 10A is a diagram schematically illustrating a lower surface of a substrate for explaining a production method for the semiconductor device shown in FIG. 8 (the step of forming continuous through-holes).

FIG. 10B is a sectional view of the semiconductor device of FIG. 8 taken along a section line A-A shown in FIG. 10A for explaining the semiconductor device production method (the step of forming the continuous through-holes).

FIG. 10C is a sectional view of the semiconductor device of FIG. 8 taken along the section line A-A shown in FIG. 10A for explaining the semiconductor device production method (the step of forming copper plating layers (first plating step)).

FIG. 10D is a diagram schematically illustrating the lower surface of the substrate for explaining the production method for the semiconductor device of FIG. 8 (the step of forming insulative resin layers (insulative resin layer forming step)).

FIG. 10E is a sectional view of the semiconductor device of FIG. 8 taken along a section line B-B shown in FIG. 10D for explaining the semiconductor device production method (insulative resin layer forming step).

FIG. 10F is a sectional view of the semiconductor device of FIG. 8 taken along the section line B-B shown in FIG. 10D for explaining the semiconductor device production method (the step of forming nickel/gold plating layers (second plating step)).

FIG. 10G is a sectional view of the semiconductor device of FIG. 8 taken along the section line B-B shown in FIG. 10D for explaining the semiconductor device production method (the step of cutting the substrate into separate support boards (cutting step)).

FIG. 11 is a sectional view of an edge portion of the semiconductor device shown in FIG. 8.

### DESCRIPTION OF REFERENCE CHARACTERS

1: Support board
1A: Upper surface (one surface)
1B: Lower surface (the other surface)
1C: Side face
2: Semiconductor chip
4: Internal terminal
5: Die pad (internal terminal)
6: External terminal
7: Groove
8: Interconnection
11: Substrate
11A: Upper surface (one surface)
11B: Lower surface (the other surface)
12: Cutting tool
13: Upper metal layer (one-side metal layer)
14: Lower metal layer (other-side metal layer)
15: Continuous through-hole
16: Copper plating layer (metal plating layer; first metal plating layer)
17: Nickel/gold plating layer (metal plating layer; second metal plating layer)
18: Recess
19: Through-hole
20: Continuous through-hole
21: Recess
22: Rectangular region
51: Burr preventing layer
52: Insulative resin layer
61: Thinner portion
62: Thicker portion
L: Section line
W: Predetermined distance

### BEST MODE FOR CARRYING OUT THE INVENTION

Embodiments of the present invention will hereinafter be described in detail with reference to the attached drawings.

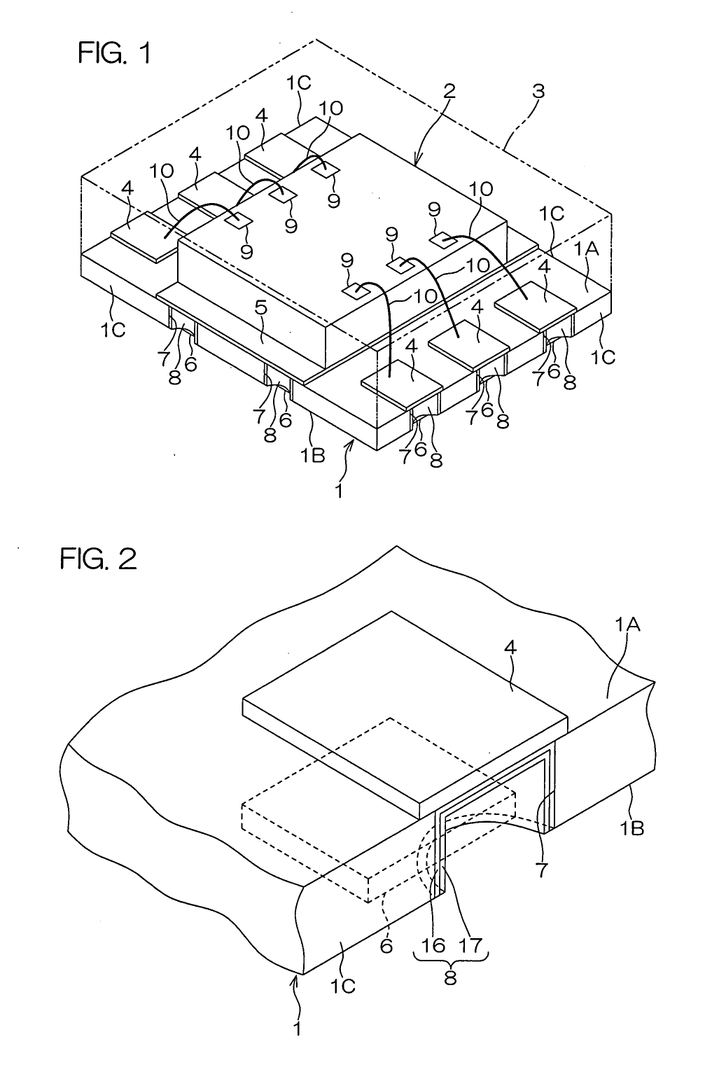

FIG. 1 is a perspective view schematically illustrating the construction of a semiconductor device according to one embodiment of the present invention. The semiconductor device includes a support board 1, a semiconductor chip 2 supported on one surface 1A (hereinafter referred to as “upper surface” as illustrated in FIG. 1) of the support board 1, and a sealing resin 3 which seals the upper surface 1A of the support board 1 and the semiconductor chip 2.

The support board 1 is composed of an insulative resin (e.g., a glass epoxy resin). The support board 1 has a rectangular plate shape.

A plurality of internal terminals 4 (three internal terminals in this embodiment) are provided on each of opposite side edge portions on the upper surface 1A of the support board 1, and arranged along the side edge at a predetermined interval. The internal terminals 4 are composed of, for example, copper, and each have a rectangular thin plate shape extending inward from the side edge of the upper surface 1A of the support board 1.

A copper die pad 5 having a rectangular plan shape, for example, is provided on a middle portion of the upper surface 1A of the support board 1 between the opposite side edge portions each formed with the internal terminals 4. The die pad 5 has a dimension which is substantially equal to the width of the support board 1 as measured in the direction of the arrangement of the plurality of internal terminals 4 on the side edge portion. Further, the die pad 5 has a width which is substantially equal to the width of the semiconductor chip 2 as measured perpendicularly to the direction of the arrangement.

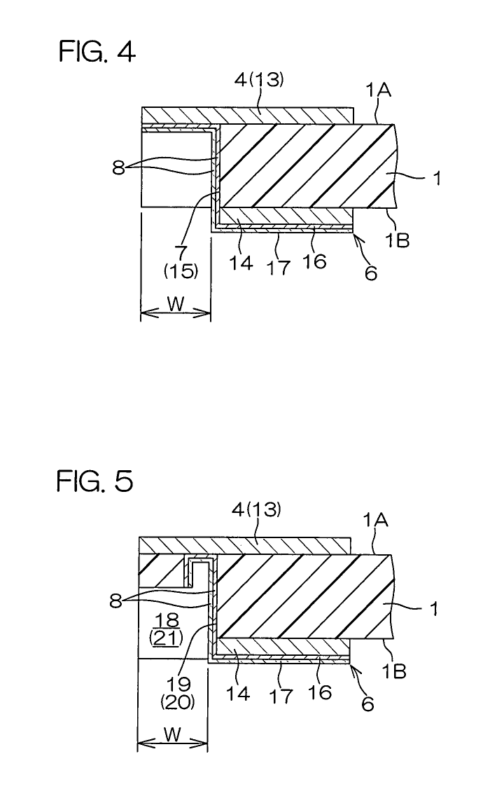

On the other hand, external terminals 6 are provided on the other surface 1B (hereinafter referred to as “lower surface” as illustrated in FIG. 1) of the support board 1 opposite from the upper surface 1A in positions which are opposed to the internal terminals 4 and the die pad 5 in the direction of the thickness of the support board 1 (perpendicularly to the upper surface 1A and the lower surface 1B). The external terminals 6 each have a rectangular thin plate shape which extends inward from a position spaced a predetermined distance W (see FIG. 4) from the corresponding side edge of the lower surface 1B of the support board 1.

The support board 1 has grooves 7 formed in four side faces 1C thereof as each extending from the external terminal 6 to the internal terminal 4 or the die pad 5 opposed to the external terminal 6 between the upper surface 1A and the lower surface 1B of the support board 1 and each having a semicircular cross sectional shape.

Interconnections 8 each composed of a metal thin layer are respectively provided on inner surfaces of the grooves 7. Ends (upper ends) of the interconnections 8 on the side of the upper surface 1A of the support board 1 are connected to the internal terminals 4 or the die pad 5. As shown in FIG. 2, ends (lower ends) of the interconnections 8 on the side of the lower surface 1B are respectively connected to the external terminals 6 at the innermost positions of the grooves 7. Thus, the internal terminals 4 are respectively electrically connected to the external terminals 6 opposed to the internal terminals 4 via corresponding ones of the interconnections 8. Further, the die pad 5 is electrically connected to the external terminals 6 opposed to the die pad 5 via corresponding ones of the interconnections 8.

As shown in FIG. 1, the semiconductor chip 2 is die-bonded onto the die pad 5 with its front surface (device formation surface) formed with functional elements facing up. A plurality of pads 9 (six pads in this embodiment) are provided on the front surface of the semiconductor chip 2. The pads 9 are respectively electrically connected to the internal terminals 4 via bonding wires 10 (by wire bonding).

The semiconductor device is mounted on a mount board (wiring board) not shown by bonding the external terminals 6 to lands (electrodes) on the mount board with the lower surface 1B of the support board 1 being opposed to the mount board.

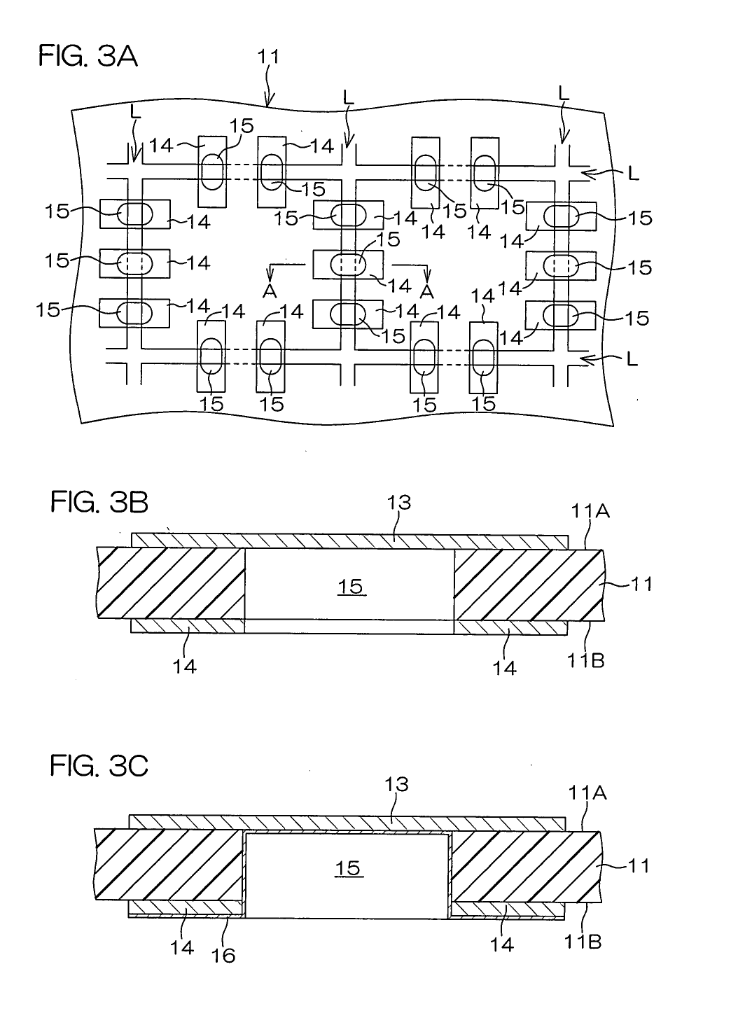

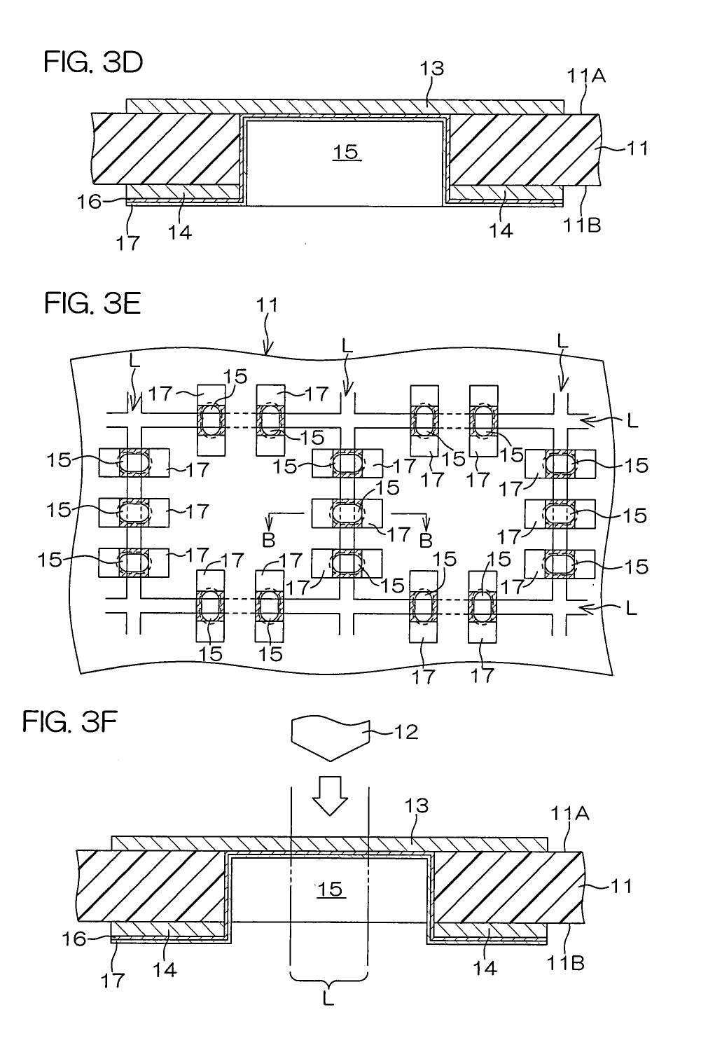

FIGS. 3A to 3F are diagrams for explaining a production method for the semiconductor device. The semiconductor device is obtained by bonding semiconductor chips 2 on one surface (upper surface) 11A of a greater size substrate 11 yet to be cut into separate support boards 1, and then cutting the substrate 11 along section lines (dicing lines) L defined in a lattice form as surrounding the semiconductor chips 2 by a cutting tool 12 such as a dicing blade.

For example, metal layers (e.g., copper layers) are preliminarily formed on the upper surface 11A of the substrate 11 and on the other surface (lower surface) 11B of the substrate 11 opposite from the upper surface 11A to entirely cover the upper and lower surfaces. Then, the metal layer on the upper surface 11A is patterned to form a plurality of upper metal layers 13 across the section lines L on the upper surface 11A. Further, the metal layer on the lower surface 11B is patterned to form lower metal layers 14 across the section lines L on the lower surface 11B in positions which are opposed to the upper metal layers 13 in the direction of the thickness of the substrate 11 (perpendicularly to the upper surface 11A and the lower surface 11B).

Thereafter, as shown in FIGS. 3A and 3B, continuous through-holes 15 each having an oval cross sectional shape are formed in positions across the section lines L as each extending continuously through the lower metal layer 14 and the substrate 11. The formation of the continuous through-holes 15 is achieved, for example, by performing a laser machining process or an etching process on the side of the lower surface 11B of the substrate 11.

In turn, as shown in FIG. 3C, copper plating layers 16 are formed on adhered to surfaces (lower surfaces) of the lower metal layers 14, inner surfaces of the continuous through-holes 15 and portions of the upper metal layers 13 exposed to the continuous through-holes 15 by performing a copper plating process on the side of the lower surface 11B of the substrate 11.

After the copper plating, a nickel plating process and a gold plating process are sequentially performed on the side of the lower surface 11B of the substrate 11. Thus, nickel/gold plating layers 17 each including a nickel plating layer and a gold plating layer are formed on surfaces of the copper plating layers 16 as shown in FIG. 3D.

Thereafter, portions of the lower metal layers 14 present on the section lines L and portions of the copper plating layers 16 and the nickel/gold plating layers 17 present on these lower metal layer portions are removed from regions (hatched in FIG. 3E) each having substantially the same length as the continuous through-hole 15 as measured perpendicularly to the section line L. The removal of the portions of the lower metal layers 14 and the portions of the copper plating layers 16 and the nickel/gold plating layers 17 is achieved, for example, by performing a laser machining process or an etching process on the side of the lower surface 11B of the substrate 11.

Then, semiconductor chips 2 are respectively bonded onto die pads 5 on the upper surface 11A of the resulting substrate 11. Subsequently, pads 9 of the semiconductor chips 2 are electrically connected to the upper metal layers 13 via bonding wires 10. Thereafter, as shown in FIG. 3F, the resulting substrate 11 is cut along the section lines L by causing the cutting tool 12 to cut into the substrate 11 from the upper surface 11A to the lower surface 11B of the substrate 11. Thus, the substrate 11 is divided into separate support boards 1.

As shown in FIG. 4, the upper metal layers 13 disposed across the section lines L are each divided into two parts by the cutting. After the division, the resulting upper metal layers 13 respectively serve as internal terminals 4 of support boards 1 on opposite sides of the section line L. By the cutting along the section lines L, the continuous though-holes 15 disposed across the section lines L are each divided into grooves 7, which are disposed in side faces 1C of the support boards 1 on the opposite sides of the section line L. Further, portions of the copper plating layers 16 and the nickel/gold plating layers 17 present on the inner surfaces of the continuous through-holes 15 and on the portions of the upper metal layers 13 exposed to the continuous through-holes 15 are each divided into two parts. After the division, the resulting copper plating layers 16 and the resulting nickel/gold plating layers 17 serve as interconnections 8 respectively connected to the internal terminals 4 of the support boards 1 on the opposite sides of the section line L. In this embodiment, the resulting lower metal layers 14 and portions of the copper plating layers 16 and the nickel/gold plating layers 17 present on surfaces of these lower metal layers 14 serve as external terminals 6 of the support boards 1.

As described above, the portions of the lower metal layers 14 on the section lines L and the portions of the copper plating layers 16 and the nickel/gold plating layers 17 on these lower metal layer portions are removed before the substrate 11 is divided into the separate support boards 1. Thus, when the substrate 11 is cut by the cutting tool 12, metals of the external terminals 6 are not present on the section lines L. Therefore, the metals of the external terminals 6 are unlikely to be dragged and drawn by the cutting tool 12. This eliminates the possibility that metal burrs occur on the external terminals 6. Accordingly, the semiconductor device has no metal burrs on the external terminals 6 thereof, and is free from electrical short-circuit between the external terminals 6 and insufficient connection (mounting failure) between the external terminals 6 and the lands on the mount board which may otherwise occur when the semiconductor device is mounted on the mount board.

FIG. 5 is a sectional view of an edge portion of a semiconductor device according to another embodiment of the present invention. In FIG. 5, components corresponding to those shown in FIG. 4 will be denoted by the same reference characters as in FIG. 4. In the following, explanation will be given only to differences from the aforementioned embodiment, but not to the same arrangements as in the aforementioned embodiment.

In the aforementioned embodiment, as shown in FIG. 4, the grooves 7 are provided in the side faces 1C of the support board 1, and the external terminals 6 on the lower surface 1B are connected to the internal terminals 4 or the die pad 5 on the upper surface 1A of the support board 1 via the interconnections 8 provided on the inner surfaces of the grooves 7. In the semiconductor device according to this embodiment, in contrast, recesses 18 dented from the lower surface 1B toward the upper surface 1A of the support board 1 and opening in the side faces 1C of the support board 1 are provided in edge portions of the support board 1. Further, through-holes 19 are provided in the support board 1 inward of the recesses 18 as extending through the support board 1 from the upper surface 1A to the lower surface 1B of the support board 1 and communicating with the recesses 18. The interconnections 8 are provided on inner surfaces of the through-holes 19, and the external terminals 6 on the lower surface 1B are connected to the internal terminals 4 or the die pad 5 on the upper surface 1A of the support board 1 via the interconnections 8.

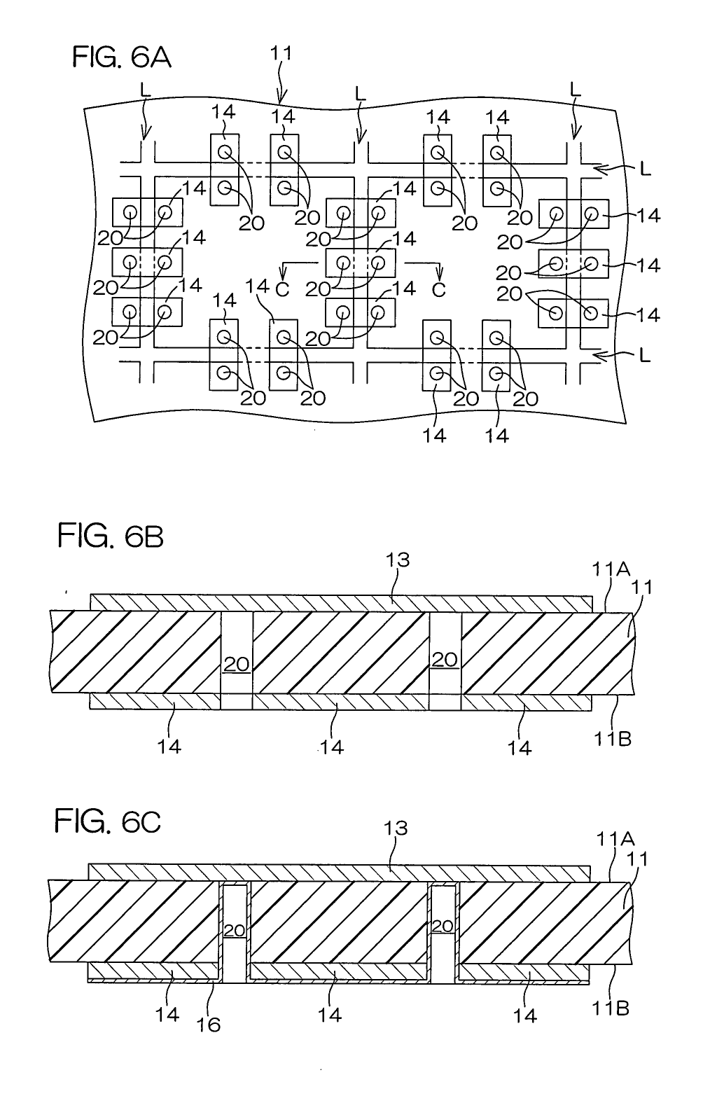

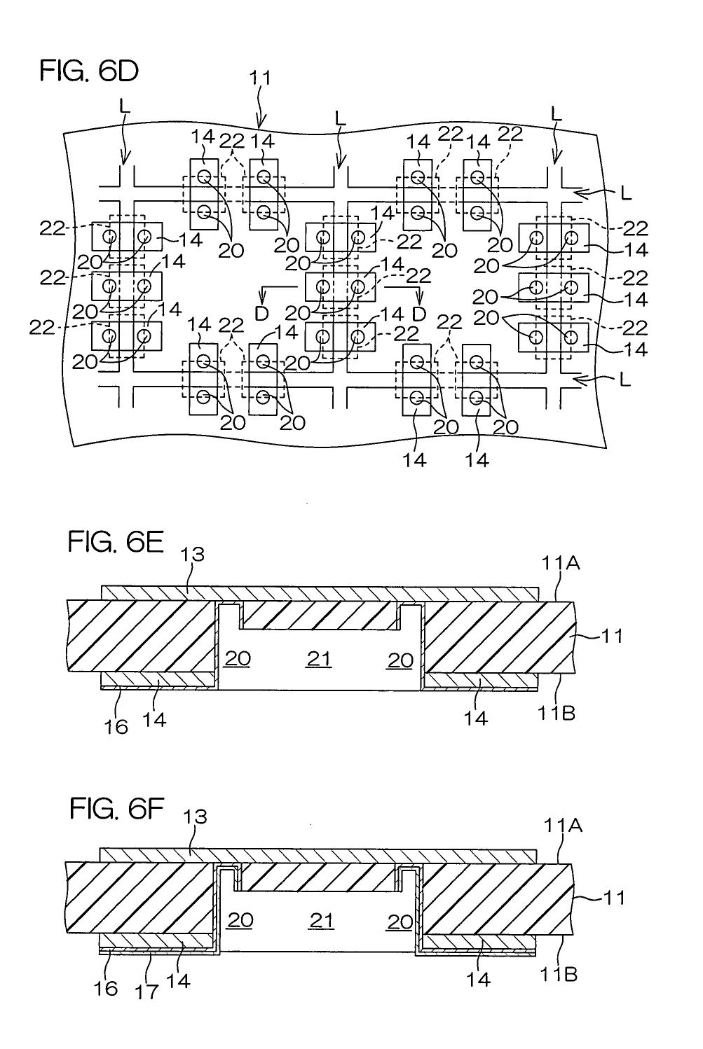

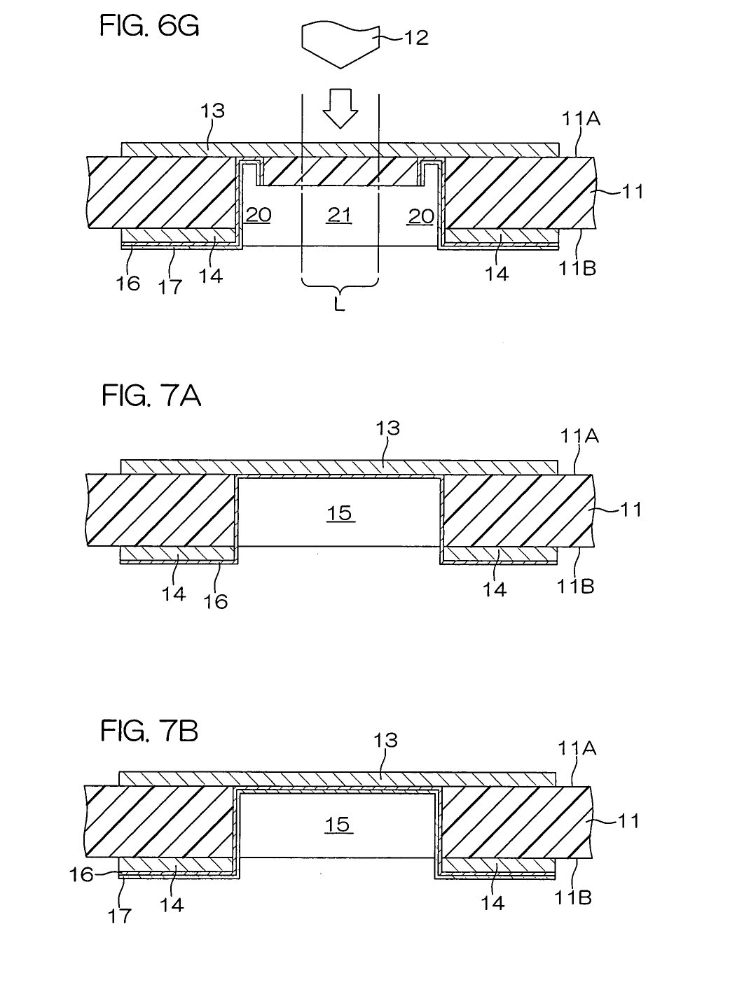

FIGS. 6A to 6G are diagrams for explaining a production method for the semiconductor device shown in FIG. 5. In this semiconductor device production method, upper metal layers 13 and lower metal layers 14 are respectively formed on an upper surface 11A and a lower surface 11B of a substrate 11 by patterning. Thereafter, as shown in FIGS. 6A and 6B, continuous through-holes 20 each having a circular cross sectional shape are respectively formed in positions symmetrical with respect to the section lines L as each extending continuously through the lower metal layer 14 and the substrate 11. The formation of the continuous through-holes 15 is achieved, for example, by performing a laser machining process or an etching process on the side of the lower surface 11B of the substrate 11.

In turn, as shown in FIG. 6C, copper plating layers 16 are formed on (adhered to) surfaces (lower surfaces) of the lower metal layers 14, inner surfaces of the continuous through-holes 20 and portions of the upper metal layers 13 exposed to the continuous through-holes 20 by performing a copper plating process on the side of the lower surface 11B of the substrate 11.

Thereafter, as shown in FIGS. 6D and 6E, recesses 21 dented from the lower surface 11B toward the upper surface 11A of the substrate 11 are each formed in a rectangular region 22 (defined by a broken line in FIG. 6D) between each two continuous through-holes 20 disposed symmetrically with respect to the section line L. The rectangular region 22 has a length not smaller than the width of the lower metal layer 14 as measured along the section line L and a width substantially equal to a distance between center axes of the two continuous through-holes 20 as measured perpendicularly to the section line L. The recesses 21 each communicate with the two continuous through-holes 20 disposed symmetrically with respect to the section line L. The formation of the recesses 21 is achieved by performing a laser machining process or an etching process on the side of the lower surface 11B of the substrate 11.

After the formation of the recesses 21, a nickel plating process and a gold plating process are sequentially performed on the side of the lower surface 11B of the substrate 11. Thus, as shown in FIG. 6F, nickel/gold plating layers 17 each including a nickel plating layer and a gold plating layer are respectively formed on surfaces of the copper plating layers 16. At this time, the nickel plating layer and the gold plating layer do not grow in regions not formed with the copper plating layers 16, so that the nickel/gold plating layers 17 are not formed in such regions.

Then, semiconductor chips 2 are respectively bonded onto die pads 5 on the upper surface 11A of the resulting substrate 11. Subsequently, pads 9 of the semiconductor chips 2 are electrically connected to the upper metal layers 13 via bonding wires 10. Thereafter, as shown in FIG. 6G, the resulting substrate 11 is cut along the section lines L by causing the cutting tool 12 to cut into the substrate 11 from the upper surface 11A to the lower surface 11B of the substrate 11. Thus, the substrate 11 is divided into separate support boards 1.

As shown in FIG. 5, the upper metal layers 13 disposed across the section lines L are each divided into two parts by the cutting. After the division, the resulting upper metal layers 13 respectively serve as internal terminals 4 of support boards 1 on opposite sides of the section line L. By the cutting along the section lines L, the recesses 21 each communicating with the two continuous through-holes 20 are each divided into two parts. After the division, the resulting recesses 21 serve as recesses 18 of the support boards 1 on the opposite sides of the section line L. The two continuous though-holes 20 serve as through-holes 19 respectively communicating with the recesses 18 of the support boards 1. Portions of the copper plating layers 16 and the nickel/gold plating layers 17 present on the inner surfaces of the through-holes 19 (continuous through-holes 20) and on the portions of the upper metal layers 13 exposed to the through-holes 19 serve as interconnections 8 respectively connected to the internal terminals 4 of the support boards 1. In this embodiment, the resulting lower metal layers 14 and portions of the copper plating layers 16 and the nickel/gold plating layers 17 present on surfaces of these lower metal layers 14 serve as external terminals 6 of the support boards 1.

In this embodiment, the continuous through-holes 20 extending continuously through each of the lower metal layers 14 and the substrate 11 are formed at the two positions symmetrical with respect to the section line L before the substrate 11 is divided into the separate support boards 1. After the formation of the copper plating layers 16, the recesses 21 are each formed in the rectangular region 22 on the section line L between the two continuous through-holes 20. Thus, when the substrate 11 is cut by the cutting tool 12, metals of the external terminals 6 and the interconnections 8 are not present on the section lines L. Therefore, the metals of the external terminals 6 and the interconnections 8 are unlikely to be dragged and drawn by the cutting tool 12. This eliminates the possibility that metal burrs occur. Therefore, the semiconductor device according to this embodiment has metal burrs neither on the external terminals 6 nor on the interconnections 8, making it possible to more reliably prevent electrical short-circuit between the external terminals 6 and insufficient connection (mounting failure) between the external terminals 6 and lands on a mount board as compared with the construction shown in FIG. 4.

In the production method shown in FIGS. 3A to 3F, the copper plating layers 16 and the nickel/gold plating layers 17 are formed in this order after the formation of the continuous through-holes 15, and then the portions of the lower metal layers 14 present on the section lines L and the portions of the copper plating layers 16 and the nickel/gold plating layers 17 present on these lower metal layer portions are removed. However, the portions of the lower metal layers 14 and the portions of the copper plating layers 16 present on these lower metal layer portions may be first removed from the regions (hatched in FIG. 3E) on the section lines L as shown in FIG. 7A after the formation of the copper plating layers 16 (see FIG. 3C), and then the nickel/gold plating layers 17 may be formed on surfaces of the resulting copper plating layers 16 as shown in FIG. 7B by sequentially performing the nickel plating process and the gold plating process on the side of the lower surface 11B of the substrate 11. The nickel plating layer and the gold plating layer do not grow in regions not formed with the copper plating layers 16 (the regions on the section lines L from which the copper plating layer portions 16 are removed), so that the nickel/gold plating layers 17 are not formed in such regions. Therefore, when the resulting substrate 11 is cut by the cutting tool 12 (see FIG. 3F), the metals of the external terminals 6 are unlikely to be dragged and drawn by the cutting tool 12. Hence, the external terminals 6 are free from metal burrs.

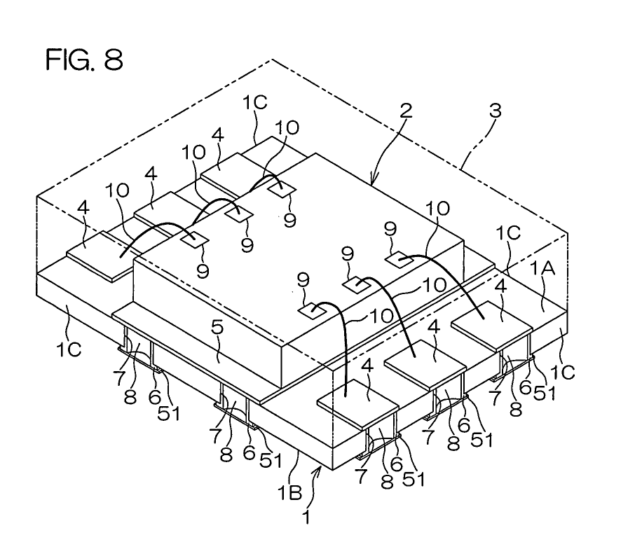

FIG. 8 is a perspective view schematically illustrating the construction of a semiconductor device according to further another embodiment of the present invention. The semiconductor device includes a support board 1, a semiconductor chip 2 supported on one surface 1A (hereinafter referred to as “upper surface 1A” as illustrated in FIG. 8) of the support board 1, and a sealing resin 3 which seals the upper surface 1A of the support board 1 and the semiconductor chip 2.

The support board 1 is composed of an insulative resin (e.g., a glass epoxy resin). The support board 1 has a rectangular plate shape.

A plurality of internal terminals 4 (three internal terminals in this embodiment) are provided on each of opposite side edge portions on the upper surface 1A of the support board 1, and arranged along the side edge at a predetermined interval. The internal terminals 4 are composed of, for example, copper, and each have a rectangular thin plate shape extending inward from the side edge of the upper surface 1A of the support board 1.

A copper die pad 5 having a rectangular plan shape, for example, is provided on a middle portion of the upper surface 1A of the support board 1 between the opposite side edge portions each formed with the internal terminals 4. The die pad 5 has a dimension which is substantially equal to the width of the support board 1 as measured in the direction of the arrangement of the plurality of internal terminals 4 on the side edge portion. Further, the die pad 5 has a width which is substantially equal to the width of the semiconductor chip 2 as measured perpendicularly to the direction of the arrangement.

On the other hand, external terminals 6 are provided on the other surface 1B (hereinafter referred to as “lower surface 1B” as illustrated in FIG. 8) opposite from the upper surface 1A of the support board 1 in positions which are opposed to the internal terminals 4 and the die pad 5 in the direction of the thickness of the support board 1 (perpendicularly to the upper surface 1A and the lower surface 1B).

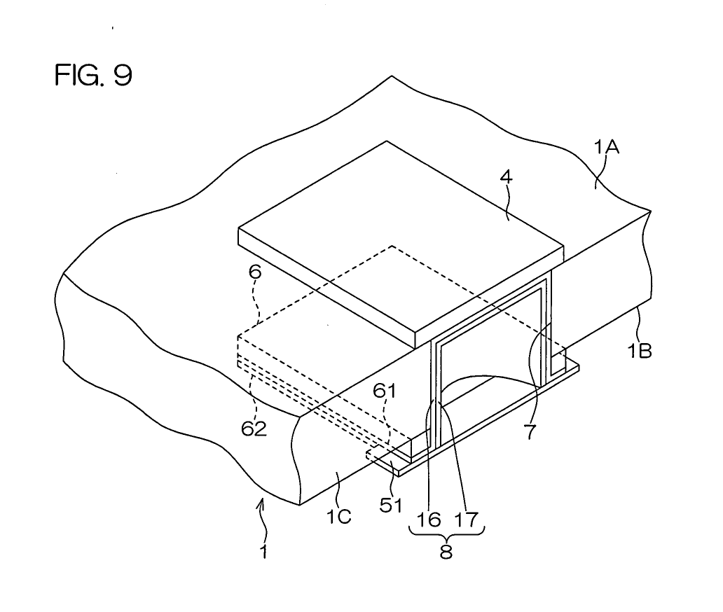

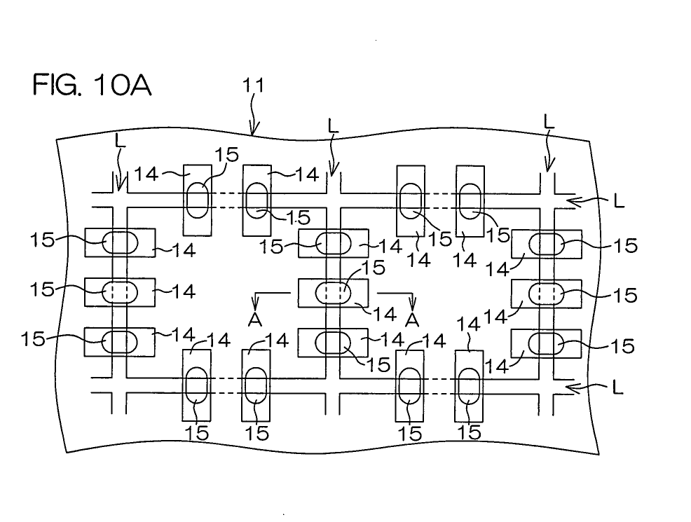

As shown in FIG. 9, the external terminals 6 each extend inward from the corresponding side edge of the lower surface 1B of the support board 1. The external terminals 6 each unitarily include a thinner portion 61 disposed along the side edge of the lower surface 1B of the support board 1 and having a relatively small thickness, and a thicker portion 62 disposed inward of the thinner portion 61 and having a relatively great thickness.

Burr preventing layers 51 of an insulative resin (e.g., a solder resist) are respectively provided below the thinner portions 61 of the external terminals 6. The burr preventing layers 51 each have a thickness which is substantially equal to a thickness difference between the thinner portion 61 and the thicker portion 62 (the height of a step between the thinner portion 61 and the thicker portion 62). The burr preventing layers 51 each have the same width as the thinner portion 61 as measured longitudinally of the external terminal 6. Thus, surfaces (lower surfaces) of the burr preventing layers 51 are respectively flush with surfaces (lower surfaces) of the thicker portions 62 of the external terminals 6 and, therefore, continuous to the surfaces of the thicker portions 62 without steps.

The support board 1 has grooves 7 formed in four side faces 1C thereof as each extending thickness wise through the external terminal 6 and the support board 1 and having a semicircular cross sectional shape.

Interconnections 8 each composed of a thin metal layer are respectively provided on inner surfaces of the grooves 7. Ends (upper ends) of the interconnections 8 on the side of the upper surface 1A of the support board 1 are connected to the internal terminals 4 or the die pad 5. As shown in FIG. 9, ends (lower ends) of the interconnections 8 on the side of the lower surface 1B are respectively connected to the external terminals 6. Thus, the internal terminals 4 are respectively electrically connected to the external terminals 6 opposed to the internal terminals 4 via corresponding ones of the interconnections 8. Further, the die pad 5 is electrically connected to the external terminals 6 opposed to the die pad 5 via corresponding ones of the interconnections 8.

As shown in FIG. 8, the semiconductor chip 2 is bonded onto the die pad 5 with its front surface (device formation surface) formed with functional elements facing up. A plurality of pads 9 (six pads in this embodiment) are provided on the front surface of the semiconductor chip 2. The pads 9 are respectively electrically connected to the internal terminals 4 via bonding wires 10 (by wire bonding).

The semiconductor device is mounted on a mount board (wiring board) not shown by bonding the external terminals 6 to lands (electrodes) on the mount board with the lower surface 1B of the support board 1 being opposed to the mount board.

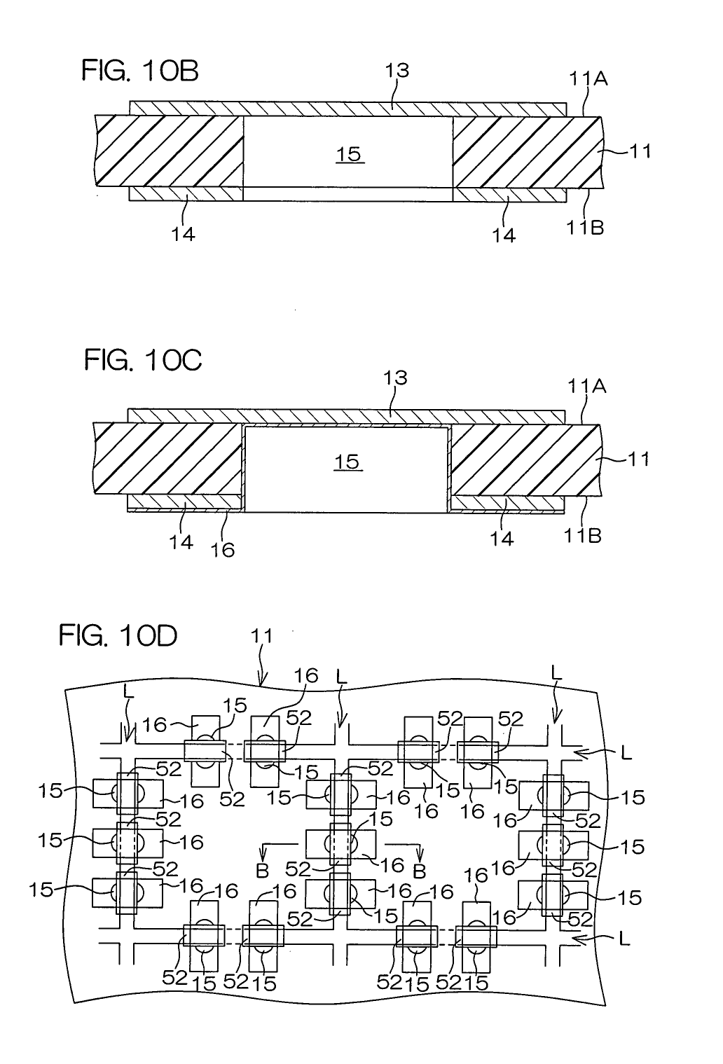

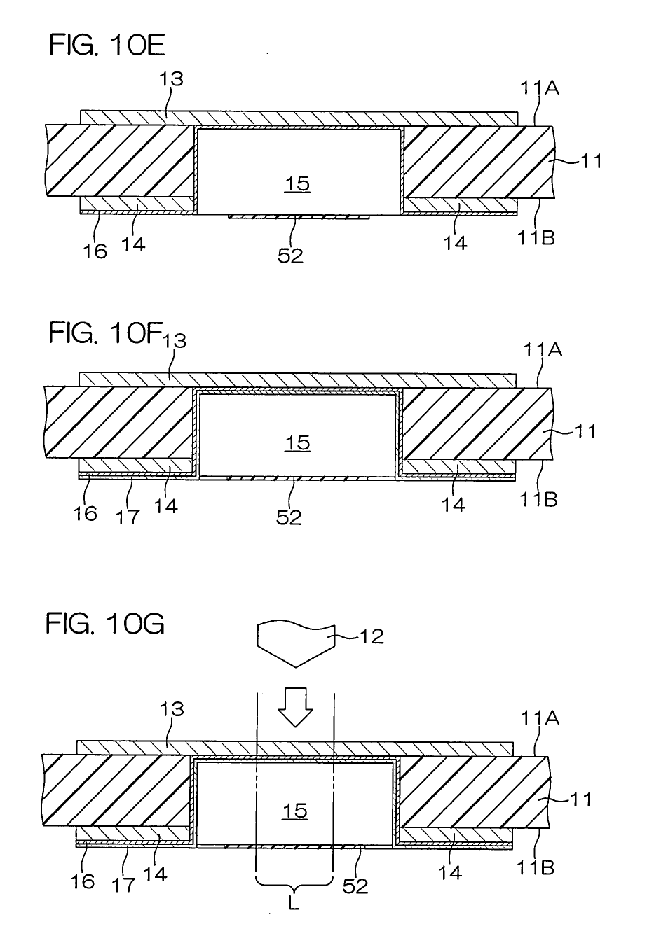

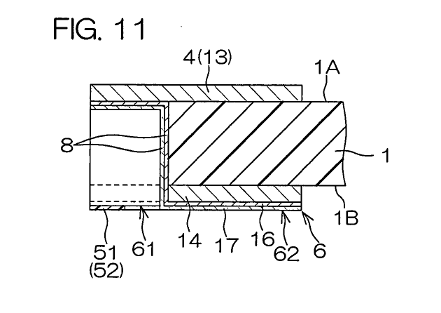

FIGS. 10A to 10G are diagrams for explaining a production method for this semiconductor device. The semiconductor device is obtained by bonding semiconductor chips 2 on one surface (upper surface) 11A of a greater size substrate 11 yet to be cut into separate support boards 1, and then cutting the substrate 11 along section lines (dicing lines) L defined in a lattice form as surrounding the semiconductor chips 2 by a cutting tool 12 such as a dicing blade.

For example, metal layers (e.g., copper layers) are preliminarily formed on the upper surface 11A of the substrate 11 and the other surface (lower surface) 11B of the substrate 11 opposite from the upper surface 11A to entirely cover the upper and lower surfaces 11A, 11B. Then, the metal layer on the upper surface 11A is patterned to form a plurality of upper metal layers 13 across the section lines L on the upper surface 11A. Further, the metal layer on the lower surface 11B is patterned to form a plurality of lower metal layers 14 across the section lines L on the lower surface 11B in positions which are opposed to the upper metal layers 13 in the direction of the thickness of the substrate 11 (perpendicularly to the upper surface 11A and the lower surface 11B).

Thereafter, as shown in FIGS. 10A and 10B, continuous through-holes 15 each having an oval cross sectional shape are formed in positions across the section lines L as each extending continuously through the lower metal layer 14 and the substrate 11. The formation of the continuous through-holes 15 is achieved by performing a laser machining process or an etching process on the side of the lower surface 11B of the substrate 11.

In turn, as shown in FIG. 10C, copper plating layers 16 are formed on (adhered to) surfaces (lower surfaces) of the lower metal layers 14, inner surfaces of the continuous through-holes 15 and portions of the upper metal layers 13 exposed to the continuous through-holes 15 by performing a copper plating process on the side of the lower surface 11B of the substrate 11.

Thereafter, as shown in FIGS. 10D and 10E, insulative resin layers 52 of an insulative resin are respectively formed on the copper plating layers 16 formed on the surfaces of the lower metal layers 14 across the section lines L so as to each cover a portion of the copper plating layer 16 across the entire width of the copper plating layer 16 defined along the section line L.

After the formation of the insulative resin layers 52, a nickel plating process and a gold plating process are sequentially performed on the side of the lower surface 11B of the substrate 11. Thus, nickel/gold plating layers 17 each including a nickel plating layer and a gold plating layer are formed on surfaces of the copper plating layers 16 as shown in FIG. 10F. The plating process is continued until surfaces (lower surfaces) of the nickel/gold plating layers 17 become substantially flush with surfaces (lower surfaces) of the insulative resin layers 52 on the lower surface 11B of the substrate 11.

After the formation of the nickel/gold plating layers 17, semiconductor chips 2 are respectively bonded onto die pads 5 on the upper surface 11A of the resulting substrate 11. Subsequently, pads 9 of the semiconductor chips 2 are electrically connected to the upper metal layers 13 via bonding wires 10. Thereafter, as shown in FIG. 10G, the resulting substrate 11 is cut along the section lines L by causing the cutting tool 12 to cut into the substrate 11 from the upper surface 11A to the lower surface 11B of the substrate 11. Thus, the substrate 11 is divided into separate support boards 1.

As shown in FIG. 11, the upper metal layers 13 disposed across the section lines L are each divided into two parts by the cutting. After the division, the resulting upper metal layers 13 respectively serve as internal terminals 4 of support boards 1 on opposite sides of the section line L. By the cutting along the section lines L, the continuous though-holes 15 disposed across the section lines L are each divided into grooves 7, which are disposed in side faces 1C of the support boards 1 on the opposite sides of the section line L. At this time, portions of the copper plating layers 16 and the nickel/gold plating layers 17 present on the inner surfaces of the continuous through-holes 15 (grooves 7) and on the portions of the upper metal layers 13 exposed to the continuous through-holes 15 are each divided into two parts. After the division, the resulting copper plating layers 16 and the resulting nickel/gold plating layers 17 serve as interconnections 8 respectively connected to the internal terminals 4 of the support boards 1 on the opposite sides of the section line L. Further, the lower metal layers 14 and portions of the copper plating layers 16 present on the lower metal layers 14 are each divided into two parts. After the division, the resulting lower metal layers 14 and the resulting copper plating layers 16, and portions of the nickel/gold plating layers 17 present on surfaces of these copper plating layers 16 serve as external terminals 6 of the support boards 1. Further, the insulative resin layers 52 disposed across the section lines L are each divided together with the lower metal layers 14 and the copper plating layers 16 into two parts. After the division, the resulting insulative resin layers 52 serve as the burr preventing layers 51 of the support boards 1 on the opposite sides of the section line L. Portions of the external terminals 6 defined between the lower surface 1B of the support board 1 and the burr preventing layers 51 each serve as a thinner portion 61 having a relatively small thickness. Portions of the external terminals 6 not contacting the burr preventing layers 51 each serve as a thicker portion 62 having a relatively great thickness.

As described above, after the copper plating layers 16 are formed on the surfaces of the lower metal layers 14 on the lower surface 11B of the substrate 11, the insulative resin layers 52 are formed so as to each cover the portion of the copper plating layer 16 on the section line L across the entire width of the copper plating layer 16 defined along the section line L. After the nickel/gold plating layers 17 are formed on the surfaces of the copper plating layers 16, the resulting substrate 11 is cut along the section lines L into the separate support boards 1.

In the cutting of the substrate 11, the cutting tool 12 is moved to cut into the substrate 11 from the upper surface 11A to the lower surface 11B of the substrate 11. The insulative resin layers 52 are present downstream of the copper plating layers 16 with respect to the direction of the movement of the cutting tool 12 relative to the substrate 11. This makes it possible to prevent the metal of the copper plating layers 16 to be dragged and drawn by the cutting tool 12, thereby preventing occurrence of metal burrs on the external terminals 6. Therefore, the semiconductor device has no metal burrs on the external terminals 6 and, hence, is free from a mounting failure such as insufficient connection between the external terminals 6 and the lands on the mount board and electrical short-circuit between the external terminals which may otherwise occur due to the metal burrs.

The burr preventing layers 51 disposed below the thinner portions 61 of the external terminals 6 each have a thickness which is substantially equivalent to the thickness difference between the thinner portion 61 and the thicker portion 62, and a width which is equal to the width of the thinner portion 61 as measured longitudinally of the external terminal 6. However, the thickness of the burr preventing layer 51 may be smaller than the thickness difference between the thinner portion and the thicker portion 62. Further, the width of the burr preventing layer 51 defined longitudinally of the external terminal 6 may be smaller than the width of the thinner portion 61. That is, the burr preventing layer 51 may be configured so as to be accommodated in a space defined by the step between the thinner portion and the thicker portion 62 of the external terminal 6.

The burr preventing layers 51 are not necessarily required, but may be omitted. A semiconductor device provided with no burr preventing layers 51 may be produced, for example, by forming the copper plating layers 16 on the surfaces of the lower metal layers 14, the inner surfaces of the continuous through-holes 15 and the portions of the upper metal layers exposed to the continuous through-holes 15 as shown in FIG. 10C, and then forming the nickel/gold plating layers 17 on the surfaces of the copper plating layers 16 except for regions extending along the section lines L and having a predetermined width across the section lines L without performing the step of forming the insulative resin layers 52 as shown in FIGS. 10D and 10E. Even without the provision of the burr preventing layers 51, the external terminals 6 each have the thinner portion 61 and the thicker portion 62. Therefore, even if metal burrs each having a length not greater than the height of the step between the thinner portion 61 and the thicker portion 62 occur on the thinner portions 61 of the external terminals 6 during the production of the semiconductor device, the metal burrs are not brought into abutment with the surface of the mount board when the semiconductor device is mounted on the mount board. Hence, the semiconductor device is free from a mounting failure such as insufficient connection between the external terminals and the lands on the mount board.

Various modifications may be made within the scope of the present invention defined by the following claims.

1. A semiconductor device comprising:
a semiconductor chip;
a support board which supports the semiconductor chip on one surface thereof;
an internal terminal provided on the one surface of the support board and electrically connected to the semiconductor chip;
an external terminal provided on the other surface of the support board opposite from the one surface and extending inward from a position spaced a predetermined distance from an edge of the support board; and
an interconnection extending through the support board from the one surface to the other surface of the support board and connecting the internal terminal and the external terminal.

2. A semiconductor device as set forth in claim 1, wherein
the support board has a groove formed in a side face thereof as extending from the one surface to the other surface thereof and opening in the side face, and
the interconnection is provided on an inner surface of the groove.

3. A semiconductor device as set forth in claim 1, wherein
the support board has a recess dented from the other surface toward the one surface thereof and opening in the side face thereof, and a through-hole extending therethrough from the one surface to the other surface thereof and communicating with the recess, and
the interconnection is provided on an inner surface of the through-hole.

4. A method of producing a semiconductor device including a semiconductor chip and a support board which supports the semiconductor chip, the method comprising the steps of:
forming a one-side metal layer in a region located across a predetermined section line on one surface of an insulative substrate;
forming an other-side metal layer on the other surface of the substrate opposite from the one surface in a position opposed to the one-side metal layer perpendicularly to the one surface;
forming a continuous through-hole extending continuously through the other-side metal layer and the substrate in a position located across the section line;
forming a metal plating layer on a surface of the other-side metal layer, an inner surface of the continuous through-hole and a portion of the one-side metal layer exposed to the continuous through-hole by plating;
after the plating step, removing a portion of the other-side metal layer and a portion of the metal plating layer which are present on the section line on the other surface of the substrate; and
after the metal removing step, cutting the resulting substrate along the section line into separate support boards by moving the substrate and a cutting tool relative to each other to cause the cutting tool to cut into the substrate from the one surface to the other surface of the substrate.

5. A method of producing a semiconductor device including a semiconductor chip and a support board which supports the semiconductor chip, the method comprising the steps of:
forming a one-side metal layer in a region located across a predetermined section line on one surface of an insulative substrate;
forming an other-side metal layer on the other surface of the substrate opposite from the one surface in a position opposed to the one-side metal layer perpendicularly to the one surface;
forming continuous through-holes each extending continuously through the other-side metal layer and the substrate in two positions located symmetrically with respect to the section line;
forming a metal plating layer on a surface of the other-side metal layer, inner surfaces of the continuous through-holes and portions of the one-side metal layer exposed to the continuous through-holes by plating;
after the plating step, forming a recess in a region located between the two continuous through-holes and having a width not smaller than a width of the other-side metal layer as measured along the section line, the recess being dented from the other surface toward the one surface of the substrate and communicating with the two continuous through-holes; and
after the recess forming step, cutting the resulting substrate along the section line into separate support boards by moving the substrate and a cutting tool relative to each other to cause the cutting tool to cut into the substrate from the one surface to the other surface of the substrate.

6. A semiconductor device comprising:
a semiconductor chip;
a support board which supports the semiconductor chip on one surface thereof;
an internal terminal provided on the one surface of the support board and electrically connected to the semiconductor chip;
an external terminal provided on the other surface of the support board opposite from the one surface and extending inward from an edge of the support board; and
an interconnection extending through the support board from the one surface to the other surface of the support board and connecting the internal terminal and the external terminal, wherein
the external terminal unitarily includes a thinner portion disposed along the edge of the support board and having a relatively small thickness, and a thicker portion disposed inward of the thinner portion and having a relatively great thickness.

7. A semiconductor device as set forth in claim 6, further comprising a burr preventing layer provided on a side of the thinner portion opposite from the support board and having a thickness not greater than a thickness difference between the thinner portion and the thicker portion.

8. A method of producing a semiconductor device including a semiconductor chip and a support board which supports the semiconductor chip, the method comprising the steps of:
forming a one-side metal layer in a region located across a predetermined section line on one surface of an insulative substrate;
forming an other-side metal layer on the other surface of the substrate opposite from the one surface in a position opposed to the one-side metal layer perpendicularly to the one surface;
forming a continuous through-hole extending continuously through the other-side metal layer and the substrate in a position located across the section line;
forming a first metal plating layer on a surface of the other-side metal layer, an inner surface of the continuous through-hole and a portion of the one-side metal layer exposed to the continuous through-hole by a first plating process;
forming a second metal plating layer on a surface of the first metal plating layer except for a region extending along the section line and having a predetermined width across the section line by a second plating process; and
after the second plating step, cutting the resulting substrate along the section line into separate support boards by moving the substrate and a cutting tool relative to each other to cause the cutting tool to cut into the substrate from the one surface to the other surface of the substrate.

9. A method of producing a semiconductor device including a semiconductor chip and a support board which supports the semiconductor chip, the method comprising the steps of:
forming a one-side metal layer in a region located across a predetermined section line on one surface of an insulative substrate;
forming an other-side metal layer on the other surface of the substrate opposite from the one surface in a position opposed to the one-side metal layer perpendicularly to the one surface;
forming a continuous through-hole extending continuously through the other-side metal layer and the substrate in a position located across the section line;
forming a first metal plating layer on a surface of the other-side metal layer, an inner surface of the continuous through-hole and a portion of the one-side metal layer exposed to the continuous through-hole by a first plating process;
after the first plating step, forming an insulative resin layer of an insulative resin across the section line on the other surface of the resulting substrate so as to cover a portion of the first metal plating layer on the other-side metal layer across an entire width of the first metal plating layer defined along the section line;
forming a second metal plating layer on a surface of the first metal plating layer by a second plating process; and
after the second plating step, cutting the resulting substrate along the section line into separate support boards by moving the substrate and a cutting tool relative to each other to cause the cutting tool to cut into the substrate from the one surface to the other surface of the substrate.
